(19) United States
(12) Patent Application Publication
(10) Pub. No.: US 2026/0165096 A1
(43) Pub. Date: Jun. 11, 2026

(54) METHOD FOR PRODUCING A COMPONENT

(71) Applicant: Fraunhofer-Gesellschaft zur Förderung der angewandten Forschung e.V., Munich (DE)

(72) Inventor: Christian Giese, Freiburg (DE)

(73) Assignee: Fraunhofer-Gesellschaft zur Förderung der angewandten Forschung e.V., Munich (DE)

(21) Appl. No.: 19/403,934

(22) Filed: Nov. 30, 2025

(30) Foreign Application Priority Data
Dec. 5, 2024 (DE) 10 2024 211 631.9

(51) Int. Cl. H10P 95/40; H10P 14/20; H10P 30/28; H10P 74/20; H10P 95/90

(52) U.S. Cl. CPC H10P 95/40; H10P 14/2903; H10P 30/28; H10P 74/203; H10P 95/90

(57) ABSTRACT

A method is provided for producing a component. A diamond layer is provided on a substrate. At least one waveguide is generated by structuring the diamond layer. Nitrogen is introduced into at least one partial volume of the waveguide. The partial volume is heated so that at least one NV center is formed, the heating of the partial volume carried out by resistance heating.

### CROSS-REFERENCE TO RELATED APPLICATIONS

This application claims priority under 35 USC § 119 to German Patent Application No. 10 2024 211 631.9, filed Dec. 5, 2024, which is hereby incorporated by reference.

### TECHNICAL FIELD

This application relates to producing components and, in particular, to producing components comprising a diamond layer on a substrate.

### BRIEF DESCRIPTION OF THE DRAWINGS

The examples may be better understood with reference to the following drawings and description. The components in the figures are not necessarily to scale.

FIG. 1 shows a first cross-section through a component according to a first embodiment;

FIG. 2 shows a second cross-section through the component according to the first embodiment;

FIG. 3 shows a longitudinal section through the component according to the first embodiment;

FIG. 4 shows a top view of the component according to the first embodiment;

FIG. 5 shows a cross-section through a component according to a second embodiment;

FIG. 6 shows a cross-section through a component according to a third embodiment;

FIG. 7 shows a possible resistance heater according to a fourth embodiment; and

FIG. 8 shows the real-time monitoring of the resistance heater during the production of the component.

### DETAILED DESCRIPTION

In one example, a method for producing a component is provided comprising: producing a diamond layer on a substrate, generating at least one waveguide by structuring the diamond layer, introducing nitrogen into at least one partial volume of the waveguide and heating at least the partial volume so that at least one NV center is formed.

It is known from EP 3 373 023 A1 to generate a plurality of waveguides on a substrate which consists of crystalline diamond. Subsequently, NV centers are generated in these waveguides. Each NV center consists of a nitrogen atom on a lattice site of the diamond lattice and an adjacent vacancy. If an NV center of this type is negatively charged, two unpaired electrons are formed in a triplet state. Due to the spin-spin interaction, this triplet state comprises a singlet state where ms=0 and a doubly degenerate doublet state where ms=±1. By applying a magnetic field, the degeneracy of the doublet is lifted so that the spectroscopic analysis of the NV center can be used as a magnetic field sensor. In addition, an NV center can be used as a quantum bit or qubit.

The known methods for producing NV centers in the diamond lattice are statistical processes, i.e. it cannot be predicted in advance exactly at which point of the substrate one or more NV centers will be formed.

However, in particular the use of NV centers as qubits requires the generation of such NV centers at precisely defined locations or spatial areas within a substrate or within a waveguide on or in a substrate. On the basis of the prior art, the object of the invention is therefore to generate color centers at predetermined locations or within a predeterminable, small partial volume of a substrate.

According to some embodiments of the invention, a method for producing a component is proposed. The component here contains at least one waveguide, in which at least one NV center is located. The component can be a magnetic field sensor or part of a quantum computer.

In order to produce the component, a diamond layer is first provided on a substrate. In some embodiments, the diamond layer can be deposited homoepitaxially or heteroepitaxially on a substrate. There can be at least one optional intermediate layer between the diamond layer and the substrate. The substrate itself can be homogeneous in structure. In some embodiments of the invention, however, the substrate itself can in turn have one or more intermediate layers. In other embodiments of the invention, the diamond layer used to produce the component can be a physically or geometrically undelimited layer or a partial volume of a homogeneous diamond substrate. According to all of the above, the substrate can be a monocrystalline diamond, which was either produced in an HPHT process or is of natural origin. In other embodiments, a diamond substrate can be overgrown with at least one further diamond layer by means of a CVD process. In yet other embodiments of the invention, the substrate can contain or consist of silicon and/or molybdenum and/or iridium and/or strontium titanate, at least one diamond layer being deposited on the substrate by means of a CVD process.

In a further method step, at least one waveguide is generated by structuring the diamond layer. This can be done by wet or dry chemical etching, the at least one waveguide being protected by means of a photoresist or another masking layer from the attack of the etchant. In some embodiments of the invention, the masking layer can contain a metal or an alloy or an oxide or a nitride. The waveguide produced in this way can be a single-mode waveguide or a multi-mode waveguide. The waveguide can be straight or curved. The waveguide can be designed and intended to direct pump light to an NV center located in the waveguide in order to transition it from its ground state to an excited state. Furthermore, the waveguide can alternatively or additionally be designed and intended to direct fluorescent light emitted by the NV center to a detector.

In order to carry out this method, nitrogen is introduced into at least one partial volume of the waveguide. In some embodiments of the invention, one or more nitrogen atoms can be implanted into the waveguide in a manner known per se by ionizing, accelerating, and focusing. In other embodiments of the invention, the nitrogen can be introduced from the gas phase during the deposition of the diamond layer. In addition, any other method is suitable that causes nitrogen to be incorporated into the crystal lattice of the diamond. In some embodiments of the invention, unavoidable impurities with nitrogen can already be sufficient to generate at least one NV center.

Finally, the partial volume is heated so that at least one NV center is formed. The formation of the NV center is here substantially based on the fact that vacancies located or generated in the crystal lattice become

mobile and diffuse to a lattice site adjacent to the nitrogen atom, so that an NV center is formed there. According to the prior art, the entire substrate is heated so that NV centers can be formed throughout the substrate, provided that nitrogen is present there.

According to the invention, it has been recognized that the generation of NV centers can be limited to a predeterminable partial volume if only this partial volume or, if necessary, a plurality of partial volumes are heated, so that only there do the vacancies become mobile and lead to the formation of NV centers. According to the invention, it is proposed to heat those locations or partial volumes of the substrate, at which NV centers shall be generated, by means of resistance heating. For this purpose, the current flow through the waveguide or the substrate is controlled in such a way that hot spots are created at predetermined locations, which lead to the generation of NV centers, whereas the temperature in the rest of the volume remains so low that there is no formation of NV centers. Since resistance heating can be carried out in a simple, quick and cost-effective way, the proposed method is particularly suitable for producing large quantities of the component.

In some embodiments of the invention, at least one partial surface of the waveguide can be coated with at least one metal layer and connected to an electrical voltage source. The metal layer can form an ohmic contact or a Schottky contact to the underlying diamond of the waveguide and in this way heat the partial volume of the waveguide by a direct current flow. Alternatively, or additionally, the current flowing in the metal layer can heat the metal layer so that the heat generated in the metal layer heats the underlying partial volume of the waveguide.

In some embodiments, the metal layer can be produced by sputtering or vapor deposition or electroplating or deposition without external current.

After completion of the proposed production method, the metal layer can be removed from the surface in whole or in part. In other embodiments of the invention, the metal layer can remain on the surface of the finished component.

In some embodiments of the invention, the structuring of the diamond layer can be carried out with a metallic hard mask, which is connected to an electrical voltage source during the subsequent heating of the partial volume. The metallic hard mask thus has a dual function. On the one hand, it is used to protect the underlying diamond from attack by the etchant and to render possible the production of a waveguide by wet or dry chemical etching. In addition, as described above, it can be used to heat the partial volume in which an NV center shall be produced by means of resistance heating. In this case, too, the metallic hard mask can be removed after the completion of the production method or left on the component.

In some embodiments of the invention, the metal layer and/or the hard mask can be structured in such a way that the cross-section thereof is reduced over at least a partial volume of the waveguide. This is helpful in particular in the case of embodiments in which the current flow occurs within the plane defined by the metal layer. Locations with a reduced cross-section within the metal layer have increased resistance, as a result of which it is there that a larger proportion of the electrical power is converted into heat which contributes to the heating of the underlying partial volume. By structuring the metal layer, the subsequent position of the NV centers within the waveguide can thus be determined with high accuracy.

In some embodiments of the invention, the partial volume can be heated to a temperature from about 700° to about 1000° or from about 800° to

about 900° or from about 750° to about 850°. In some embodiments of the invention, the substrate or the prefabricated semi-finished product of the component can be introduced into a vacuum chamber when heating the at least one partial volume. This can prevent or reduce the oxidation of the diamond surface and/or graphitization of the diamond, so that the waveguide can have an improved crystal quality.

In some embodiments of the invention, the waveguide can be connected to the substrate via at least one connecting bridge. In some embodiments, the waveguide adjacent to the connecting bridges can be arranged in free-standing fashion above the substrate, i.e. there is a gap between the underside of the waveguide and the surface of the substrate. If a current is introduced via the surface of the waveguide and is dissipated via the substrate surface, the electrical power density concentrates over the connecting bridges, so that a partial volume adjacent to the connecting bridges is heated more strongly in each case than the surrounding material. It is thus possible to generate individual NV centers in a well-targeted fashion in at least one partial volume above a connecting bridge.

In some embodiments of the invention, the connecting bridge can run parallel to the plane defined by the substrate surface. The connecting bridge thus engages laterally with the waveguide. In other embodiments of the invention, the connecting bridge can run parallel to the normal vector of the plane defined by the substrate surface. The waveguide is thus connected to the substrate surface in a manner similar to a bridge structure with underlying supports.

In some embodiments of the invention, the waveguide can be connected to the substrate via at least one insulating intermediate layer. This can facilitate the operation of the finished component. In addition, the intermediate layer can represent a defined thermal transfer resistance and/or a defined electrical resistance between the waveguide and the substrate, so that it is possible by means of the shape, material, doping and/or thickness of the intermediate layer to select in well targeted fashion partial volumes of the waveguide which are heated to a higher temperature than adjacent areas, so that NV centers can be specifically created in the warmer partial volumes.

In some embodiments of the invention, the waveguide and/or the substrate can be contacted with a contact needle for resistance heating. The contact needle can consist of a metallic material or contain a metallic material. The contact needle represents on the one hand a transition resistance to the adjacent waveguide. In addition, the point-like contact of the contact needle generates a high current density within the underlying diamond material, so that a higher temperature or a stronger heating can prevail below the contact needle than at a greater distance from the contact needle. The spatially inhomogeneous heating can in turn influence the location of the formation of the NV center.

In some embodiments of the invention, pump light can be coupled into the waveguide during the resistance heating, the resistance heating of the partial volume being terminated as soon as fluorescent light from the NV center is identified. This allows the production process of the NV center to be monitored in real time, so that the formation of an undesirable multitude of NV centers can be reliably prevented. On the contrary, the proposed method allows individual NV centers to be generated at predeterminable locations in well-calculated fashion and thus also at a predeterminable distance from one another.

In some embodiments of the invention, the pump light can be generated by means of a laser light source. In some embodiments of the invention, the pump light can be generated from the green spectral range. In some embodiments of the invention, the fluorescent light can be assigned to the red spectral range. In order to increase the accuracy, the fluorescent light can be detected via a spectrometer and/or a narrow-band filter in order to avoid interference from the pump light.

The invention will now be explained in more detail below with reference to drawings without limiting the general concept of the invention.

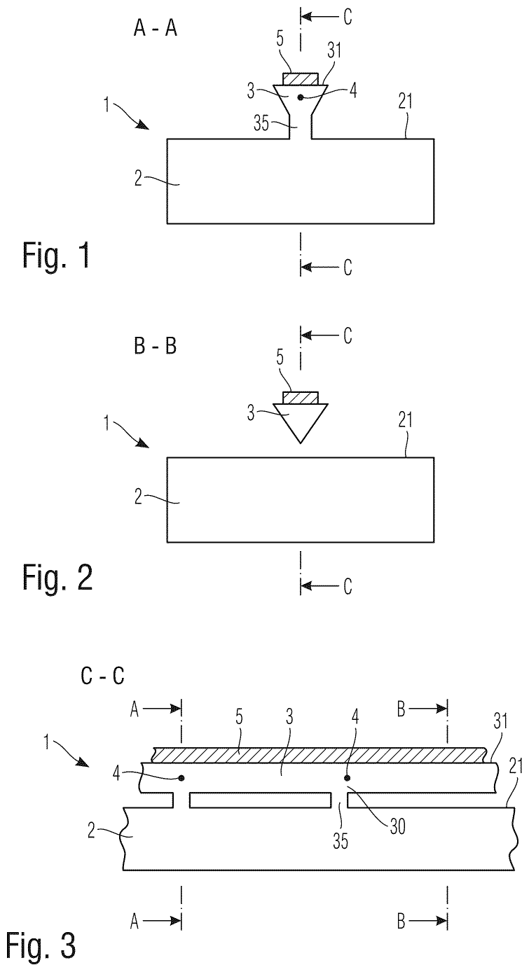

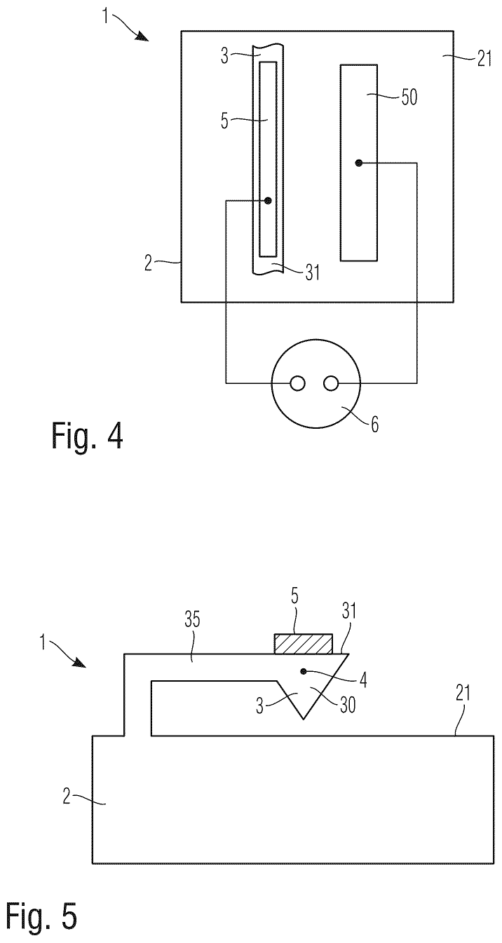

FIGS. 1 to 4 are used to explain a first embodiment of the invention in more detail. FIG. 3 here shows a longitudinal section through the component 1, whereas FIGS. 1 and 2 show two different cross-sections and FIG. 4 shows the top view.

As can be seen from FIG. 3, the component 1 has a substrate 2. The substrate 2 can contain or consist of diamond. The substrate 2 can be overgrown with a diamond layer produced homoepitaxially by low-pressure synthesis. Alternatively, the substrate 2 can also contain or consist of a metal or a semiconductor, in particular silicon, molybdenum, iridium, or tungsten. In yet other embodiments of the invention, the substrate 2 can contain or consist of a ceramic material, for example strontium titanate or silicon carbide. In each case, the substrate has a diamond layer, either in the form of a near-surface partial volume of the substrate homogeneous per se or in the form of a diamond layer that is homoepitaxially or heteroepitaxially deposited from the gas phase.

As can be seen in FIGS. 1 to 3, at least one waveguide 3 is generated on the substrate 2. The waveguide 3 is generated by structuring the diamond layer, i.e. by means of masking and wet or dry chemical etching. The diamond layer can here be masked with a hard mask made of metal or a ceramic material or also by means of a polymer photoresist. By structuring the diamond layer, at least one waveguide 3 is exposed so that it is raised above the surface 21 of the substrate 2. In the illustrated exemplary embodiment, the waveguide 3 has a triangular cross-section. In other embodiments of the invention, the cross-section of the waveguide 3 can also have a different polygonal or even round shape. The waveguide 3 is designed and intended to guide optical radiation, in particular visible

light, by total reflection at its interfaces, so that it propagates along the longitudinal extension of the waveguide 3.

In the illustrated exemplary embodiment, the waveguide 3 is connected to the substrate 2 via a plurality of connecting bridges 35. The connecting bridges 35 here run parallel to the normal vector of the plane defined by the substrate surface 21. The connecting bridges 35 are thus similar to bridge piers below the waveguide 3. This is shown in FIG. 1. At other points along its longitudinal extension, the waveguide 3 has no connecting bridges 35. It is thus arranged to be spaced above the surface 21 of the substrate 2. This is shown in FIG. 2.

The method is further characterized in that nitrogen is introduced or has been introduced into at least one partial volume 30 of the waveguide 3. The nitrogen can also be present homogeneously in the material of the waveguide 3. The nitrogen can be introduced before the at least one waveguide 3 is produced, for example by implantation. In other embodiments of the invention, the nitrogen can also be introduced into the diamond layer from the gas phase during the low-pressure synthesis. In some embodiments of the invention, unavoidable impurities with nitrogen during the production of the substrate 2 or the diamond layer can already cause a sufficient concentration of nitrogen atoms on lattice sites within the diamond of the waveguide 3.

In the next step of the method, at least one partial volume 30 is heated locally so that vacancies in the diamond lattice become mobile and diffuse to a lattice site adjacent to a nitrogen atom. This results in the formation of at least one NV center in the heated partial volume 30. In some embodiments of the invention, exactly one NV center can be generated in each partial volume 30.

The partial volume 30 is heated by resistance heating. For this purpose, at least one metal layer 5 is used, which is applied to the entire surface 31 of the waveguide 3 or at least as a partial coating. In addition, the surface 21 of the substrate 2 can be provided with a counter electrode 50. The metal layer 5 and/or the counter electrode 50 can be generated, for example, by thermal evaporation or by sputtering or by deposition without external current or electroplating. The metal layer 5 and the counter electrode 50 can form an ohmic contact to the underlying material. In other embodiments of the invention, the metal layer 5 and/or the counter electrode 50 can form a Schottky contact to the underlying material. In some embodiments of the invention, the counter electrode 50 can have a larger surface area in order to keep the current density below the counter electrode 50 and thus the electrical resistance and the heat generated below the counter electrode 50 low.

As shown in FIG. 4, the metal layer 5 and the counter electrode 50 are connected to a current or voltage source 6. Although only a voltage source is mentioned below for improved readability, a current source is always included in the description. The voltage source 6 can generate a direct or alternating voltage and in this way initiate an electric current flow from the metal layer 5 via the material of the waveguide 3 and the connecting bridges 35 into the substrate 2 and from there via the counter electrode 50 back to the voltage source 6. Due to the electrical resistance inherent in the materials, the current flow leads to heating. The heating is stronger, the greater the electrical resistance and/or the greater the spatially inhomogeneous current density at individual points. As can be seen from FIG. 3 and FIG. 1, the current impressed into the waveguide 3 flows via the connecting bridges 35 into the substrate 2. At the location of the connecting bridges 35, which have a smaller cross-section compared to the waveguide 3, there is therefore an increased current density, which leads to locally increased heating of the waveguide 3.

Thus, the temperature in the partial volumes 30 adjacent to the connecting bridges 35, can rise locally to such an extent that NV centers 4 are formed there, whereas the remaining volume of the waveguide 3 remains so cool that the vacancies in the crystal lattice do not become mobile and no NV centers are formed. The shape, the cross-section, the number and position of the connecting bridges 35 can thus influence the number and position of the resulting NV centers without the need for complex micro-material processing, for example by means of an AFM tip or a transmission electron microscope. Through simple, comparatively large metallization and a single current supply, a plurality of NV centers can be established at precisely defined locations.

The local heating in the partial volumes 30 can here reach between about 800° C. and about 900° C., whereas adjacent spatial areas of the waveguide 3 as well as the substrate 2 remain significantly cooler, for example below 700° C. In some embodiments, the current supply and subsequent heating can take place in a protective gas atmosphere or a vacuum chamber in order to avoid negative effects on the crystal quality of the waveguide 3, for example due to graphitization or oxidation.

After the NV centers have been produced, the connection to the voltage source 6 can be removed. The metal layer 5 and/or the counter electrode 50 can be left on the component or be removed by wet or dry chemical etching.

A second embodiment of the invention is explained in more detail with reference to FIG. 5. Identical components of the invention are designated by the same reference signs, so that the following description is limited to the essential differences.

FIG. 5 shows a cross-section through the component 1 analogous to FIG. 1. As can be seen from FIG. 5, the second embodiment differs from the above described first embodiment in that the connecting bridge 35 runs parallel to the plane defined by the substrate surface 21. This allows the connecting bridge 35 to be extended so that it has a greater electrical resistance and the heat can be generated more quickly in the partial volume 30. In addition, optical crosstalk from the waveguide 3 into the substrate 2 can be reduced during the subsequent operation of the component 1.

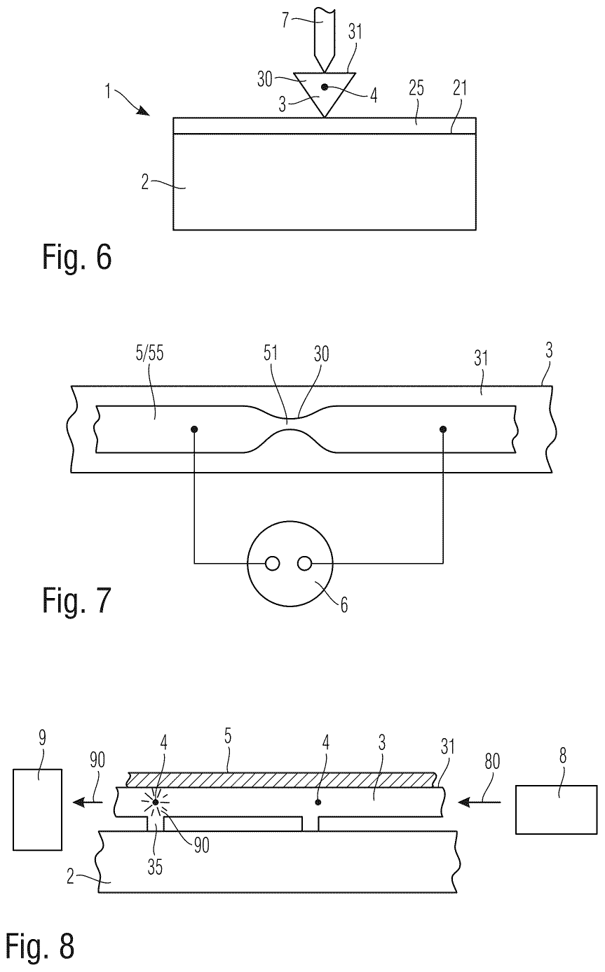

FIG. 6 illustrates a third embodiment of the invention in more detail. In this case, too, identical components of the invention are designated by the same reference signs. FIG. 6 shows that instead of the connecting bridges 35, there is a substantially insulating intermediate layer 25. The intermediate layer 25 is located on the first side 21 of the substrate 2. The intermediate layer 25 can contain or consist of nominally undoped diamond or silicon. Alternatively, the intermediate layer 25 can be an oxide, a nitride, or an oxynitride, or can contain a material of this type. In some embodiments of the invention, the intermediate layer 25 can represent a constant electrical resistance between the waveguide 3 and the substrate 2. In other embodiments of the invention, the intermediate layer 25 can have a locally different electrical resistance, for example by doping or by reduced layer thickness. In this case, the insulating intermediate layer can thus cause a locally increased current flow in the partial volumes 30 and thus increased heating, as already described above for the connecting bridges 35. In this case, the electric current can be introduced via a metal layer 5 as described above with reference to the first exemplary embodiment.

FIG. 6 describes an alternative form of resistance heating. For this purpose, the waveguide 3 is contacted with at least one contact needle

7. The contact needle 7 is located above a partial volume 30, so that an increased current density and, as a result, increased heating is generated there, which leads to the formation of an NV center 4. If a plurality of NV centers shall be generated, a plurality of contact needles can be applied, for example in the form of a needle card known per se with a plurality of spring-mounted needle contacts.

It should be noted that the resistance heating via at least one needle contact 7 instead of the metal layer 5 can also be used with the embodiments described above with reference to FIGS. 1-5. Similarly, the intermediate layer 25 according to FIG. 6 can also be combined with a resistance heater via a metal layer 5 according to one of the above FIGS. 1-5.

FIG. 7 illustrates a further embodiment of the invention in more detail. According to this embodiment, the current flow does not occur, or only occurs to a small extent via the waveguide 3 into the underlying substrate

2. On the contrary, the majority of the current flow occurs within the plane defined by the metal layer 5 and thus along the surface 31 of the waveguide 3.

FIG. 7 also shows the use of a hard mask 55 for the resistance heating of the waveguide 3. The hard mask 55 here contains a metallic material which protects the waveguide 3 from attack by the etchant during its production. Following the production of the waveguide, the hard mask 55 is masked again and partially removed by etching, so that at least one constriction 51 is formed above the partial volume 30. However, a person skilled in the art will recognize that the method shown in FIG. 7 can be carried out not only with a hard mask 55 but also in the same way with a dedicated metal layer 5 which, as described above, was applied exclusively for resistance heating.

As can be seen from FIG. 7, the constriction 51 has a reduced conductor cross-section, so that the electrical resistance of the hard mask 55 or the metal layer 5 increases locally at this point. This leads to an increased electrical power loss and subsequently to increased heating of the partial volume 30 adjacent to the constriction 51, so that an NV center can be formed there at a precisely defined location. This form of resistance heating can be used in all of the embodiments of component 1 described above with reference to FIGS. 1-6.

FIG. 8 illustrates in more detail an alternative method that can be combined with all the variants described above. As can be seen in FIG. 8, pump light 80 from a pump light source 8 is coupled into the waveguide 3 during the resistance heating of the waveguide 3. The pump light source 8 can be a laser light source, for example a semiconductor laser. In some embodiments of the invention, the pump light 80 can contain or consist of green laser light.

The pump light 80 leads to the optical excitation of an NV center 4 as soon as it has been created. The NV center relaxes while emitting red fluorescent light with a wavelength of approximately 638 nm. The fluorescent light 90 can be detected in a detector 9. The detector 9 can have a narrow-band filter or a spectrometer in order to render possible the fluorescent light 90 to be distinguished from the pump light 80.

Once the fluorescent light 90 has been detected in the detector 9 the resistance heating is switched off. The local heating of the small partial volume 30 immediately drops below the temperature required for the formation of NV centers, since the heat is rapidly distributed throughout the remaining volume of the waveguide 3 due to the high thermal conductivity of the diamond. This prevents the formation of further NV

centers in the partial volume 30, making the method particularly suitable for producing individual NV centers at precisely defined locations within the waveguide 3.

To clarify the use of and to hereby provide notice to the public, the phrases “at least one of <A>, <B>, . . . and <N>” or “at least one of <A>, <B>, . . . or <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed. Unless otherwise indicated or the context suggests otherwise, as used herein, “a” or “an” means “at least one” or “one or more.”

Of course, the invention is not limited to the illustrated embodiments. The above description should therefore be regarded as explanatory rather than restrictive. The following claims should be understood in such a way that an indicated feature is present in at least one embodiment of the invention. This does not exclude the presence of further features. The following claims should not be understood as meaning that an indicated feature is present in every embodiment of the invention. Where the claims and the above description define “first” and “second” embodiments, this designation is used to distinguish between two similar embodiments without establishing an order of priority.

1. Method for producing a component, comprising:
providing a diamond layer on a substrate;
generating at least one waveguide by structuring the diamond layer;
introducing nitrogen into at least one partial volume of the waveguide; and
heating the partial volume so that at least one NV center is formed,
wherein the partial volume is heated by resistance heating.

2. The method of claim 1, wherein at least one metal layer is applied to at least one partial surface of the waveguide and connected to an electrical voltage source.

3. The method of claim 1, wherein the structuring of the diamond layer is carried out with a metallic hard mask, which is connected to an electrical voltage source during the subsequent heating of the partial volume.

4. The method of claim 3, wherein the metal layer and/or the hard mask is structured in such a way that its cross-section over the partial volume is reduced.

5. The method of claim 1, wherein the waveguide is connected to the substrate via at least one connecting bridge.

6. The method of claim 5, wherein the partial volume is adjacent to the connecting bridge.

7. The method of claim 5, wherein the connecting bridge runs parallel to the plane defined by the substrate surface or in that the connecting bridge runs parallel to the normal vector of the plane defined by the substrate surface.

8. The method of claim 1, wherein the current flow of the resistance heater occurs within the plane defined by the metal layer and/or the hard mask or in that the current flow of the resistance heater occurs from the waveguide to the substrate.

9. The method of claim 1, wherein the introduction of nitrogen is carried out by means of implantation or in that the production of a diamond layer is carried out by means of low-pressure synthesis and nitrogen is introduced from the gas phase.

10. The method of claim 1, wherein the waveguide is connected to the substrate via at least one insulating intermediate layer.

11. The method of claim 1, wherein the waveguide and/or the substrate are contacted with a contact needle for resistance heating.

12. The method of claim 1, wherein during resistance heating, pump light is coupled into the waveguide and the resistance heating of the partial volume is terminated as soon as fluorescent light from the NV center is identified.
